(19) United States
(12) Patent Application Publication
(10) Pub. No.: US 2026/0100557 A1
(43) Pub. Date: Apr. 9, 2026

(54) SEMICONDUCTOR LASER

(71) Applicant: Lumentum Operations LLC, San Jose, CA (US)

(72) Inventors: Masato ITO, Sagamihara (JP); Akinori HAYAKAWA, Sagamihara (JP)

(21) Appl. No.: 19/058,929

(22) Filed: Feb. 20, 2025

(30) Foreign Application Priority Data
Oct. 7, 2024 (JP) 2024176066
Jan. 6, 2025 (JP) 2025001188

(51) Int. Cl. H01S 5/12; H01S 5/20

(52) U.S. Cl. CPC H01S 5/124; H01S 5/2018

(57) ABSTRACT

Some implementations described herein include a semiconductor laser having a distribution of a coupling coefficient. The semiconductor laser includes a substrate, and a semiconductor multilayer. The semiconductor multilayer includes an active layer, a grating layer, and an optical confinement adjustment layer which is flat. The semiconductor multilayer forms a first region and a second region. The optical confinement adjustment layer includes a high refractive index region, and a low refractive index region having a refractive index lower than a refractive index of the high refractive index region. The high refractive index region is arranged in any one of the first region or the second region and the low refractive index region is arranged in another one of the first region or the second region so that a first coupling coefficient of the first region becomes larger than a second coupling coefficient of the second region.

### CROSS-REFERENCE TO RELATED APPLICATION

This Patent Application claims priority to Japan Patent Application No. JP2025-001188, filed on Jan. 6, 2025, and Japan Patent Application No. JP2024-176066, filed on Oct. 7, 2024. The disclosures of the prior Applications are considered part of and are incorporated by reference into this Patent Application.

### TECHNICAL FIELD

The present disclosure relates generally to a semiconductor laser.

### BACKGROUND

Semiconductor lasers are widely used as a light source in optical communications. A distributed feedback semiconductor laser (DFB laser) is one type of a semiconductor laser. A DFB laser includes a grating. Further, a structure that includes a phase shift portion within the grating can improve characteristics of the DFB. A stable single-wavelength operation can be obtained by forming an anti reflection film (e.g., a low reflection film) on both facets of a semiconductor laser and arranging a λ/4 shift portion in the grating. For example, some structures provide a distribution in the coupling coefficient κ, which indicates the intensity of interaction between a grating structure and light, along the direction in which a resonator is formed.

### SUMMARY

A distribution can be provided in a coupling coefficient by changing a height of a grating in an optical axis direction. Although the height of the grating in the optical axis direction is constant, a distribution can be formed by changing a thickness or a composition of a layer to be buried within the grating. However, in order to achieve a desired distribution of the coupling coefficient with those methods, precise film thickness control is required.

Some implementations described herein include a semiconductor laser having a distribution of a coupling coefficient.

In some implementations, a semiconductor laser includes a substrate, and a semiconductor multilayer arranged above the substrate. The semiconductor multilayer includes an active layer, a grating layer, and an optical confinement adjustment layer which is flat. The semiconductor multilayer forms a first region and a second region in a first direction in which the grating layer extends. The optical confinement adjustment layer includes a high refractive index region, and a low refractive index region having a refractive index lower than a refractive index of the high refractive index region. The high refractive index region is arranged in any one of the first region or the second region and the low refractive index region is arranged in another one of the first region or the second region so that a first coupling coefficient of the first region becomes larger than a second coupling coefficient of the second region.

### BRIEF DESCRIPTION OF THE DRAWINGS

FIG. 1 is a top view for illustrating a semiconductor laser according to a first example implementation of the present invention.

FIG. 2 is a schematic sectional view taken along the line II-II of the semiconductor laser illustrated in FIG. 1.

FIG. 3 is a schematic sectional view taken along the line III-III of the semiconductor laser illustrated in FIG. 1.

FIG. 4 is a schematic sectional view taken along the line IV-IV of the semiconductor laser illustrated in FIG. 1.

FIG. 5 is a graph for showing calculation results indicating a relationship between a thickness of an optical confinement adjustment layer and a coupling coefficient.

FIG. 6 is a schematic sectional view for illustrating a semiconductor laser according to a second example implementation of the present invention.

FIG. 7 is a schematic sectional view for illustrating the semiconductor laser according to the second example implementation.

FIG. 8 is a schematic sectional view for illustrating the semiconductor laser according to the second example implementation.

FIG. 9 is a schematic sectional view for illustrating a semiconductor laser according to a third example implementation of the present invention.

FIG. 10 is a schematic sectional view for illustrating a semiconductor laser according to a fourth example implementation of the present invention.

FIG. 11 is a schematic sectional view for illustrating a semiconductor laser according to a fifth example implementation of the present invention.

FIG. 12 is a top view for illustrating a semiconductor laser according to a sixth example implementation of the present invention.

FIG. 13 is a schematic sectional view taken along the line XIII-XIII of the semiconductor laser illustrated in FIG. 12.

FIG. 14 is a schematic sectional view taken along the line XIV-XIV of the semiconductor laser illustrated in FIG. 12.

FIG. 15 is a schematic sectional view taken along the line XV-XV of the semiconductor laser illustrated in FIG. 12.

### DETAILED DESCRIPTION

The following detailed description of example implementations refers to the accompanying drawings. The same reference numbers in different drawings may identify the same or similar elements. Members denoted by the same reference symbol throughout the drawings have the same or an equivalent function, and a repetitive description on the members is omitted. Note that sizes of graphics are not always to scale.

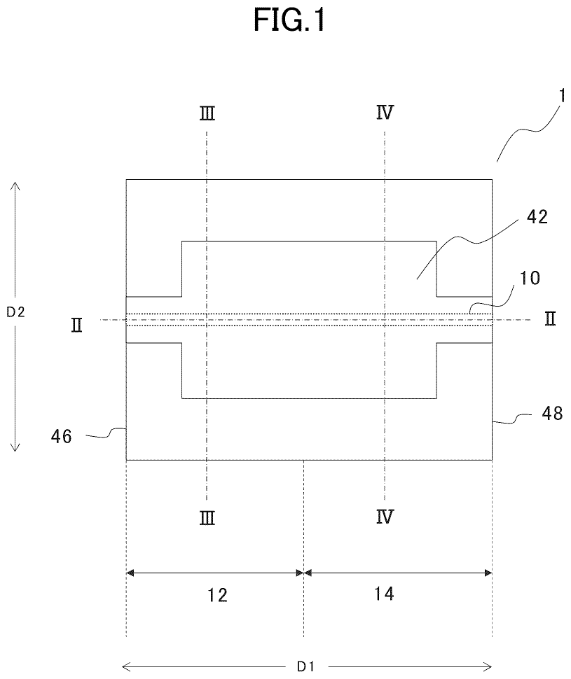

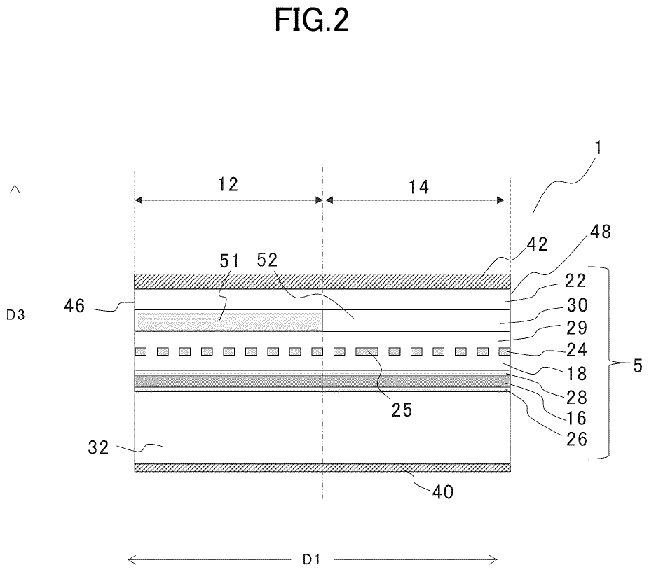

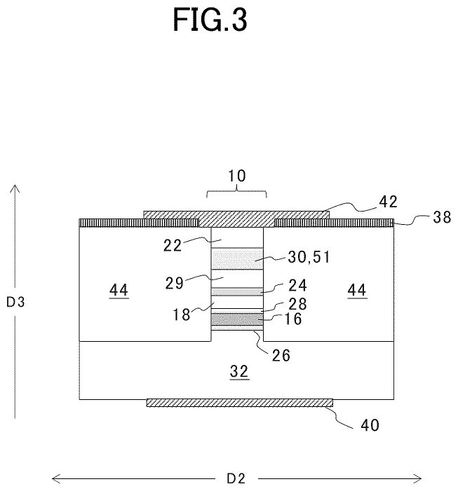

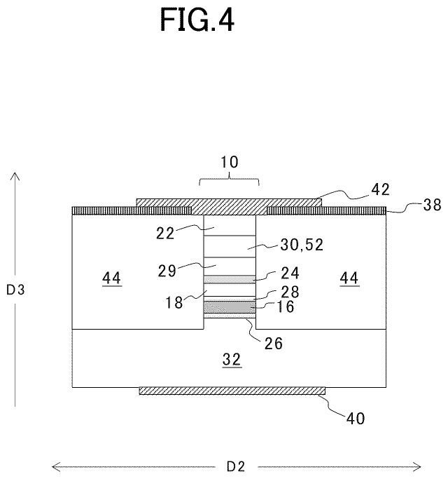

FIG. 1 is a top view for illustrating a semiconductor laser 1 according to a first example implementation of the present invention. FIG. 2 is a schematic sectional view taken along the line II-II of the semiconductor laser 1 illustrated in FIG. 1. FIG. 3 is a schematic sectional view taken along the line III-III of the semiconductor laser 1 illustrated in FIG. 1. FIG. 4 is a schematic sectional view taken along the line IV-IV of the semiconductor laser 1 illustrated in FIG. 1. The semiconductor laser 1 is an edge-emitting laser, and may be a continuous oscillation laser or a direct-modulation laser.

The semiconductor laser 1 includes a substrate 32. The substrate 32 may be a semiconductor substrate of a first conductivity type. For example, the substrate 32 may be an n-type InP substrate. The semiconductor laser 1 may include a mesa structure 10 above the substrate 32. The mesa structure 10 may include a semiconductor multilayer 5. The lowermost layer of the mesa structure 10 may include a part of the substrate 32, but the lowermost layer of the mesa structure 10 is not required to include a part of the substrate 32. The semiconductor multilayer 5 may be defined by layers arranged above the substrate 32. In this case, the substrate 32 also functions as a cladding layer of the first conductivity type. Here, a direction in which the mesa structure 10 extends may be represented by a first direction D1, and a direction perpendicular to the first direction D1 in plan view may be represented by a second direction D2. In the second direction D2, a width of the mesa structure 10 may be the same throughout a region in which a grating layer 24 to be described later is arranged. The width of the mesa structure 10 is not always required to be constant in the second direction D2. For example, in a phase shift portion 25 to be described later, a structure in which a phase is shifted by changing the width of the mesa structure 10 may be adopted.

The semiconductor multilayer 5 may include a first optical confinement layer 26, an active layer 16, a second optical confinement layer 28, a spacer layer 18, the grating layer 24, a first cladding layer 29, an optical confinement adjustment layer 30, and a second cladding layer 22. The first optical confinement layer 26 may be of the first conductivity type. The active layer 16 may be a multiple quantum well (MQW) layer in which a plurality of quantum well layers and a plurality of barrier layers are alternately grown, or may be other structures. The second optical confinement layer 28 may be of a second conductivity type, which may be opposite to the first conductivity type. In this case, the second optical confinement layer 28 may be of a “p” type. The first optical confinement layer 26, the active layer 16, and the second optical confinement layer 28 may be formed of, for example, InGaAsP or InGaAlAs. The first optical confinement layer 26 and/or the second optical confinement layer 28 may be omitted. The spacer layer 18 may be a layer arranged between the active layer 16 and the grating layer 24.

The spacer layer 18 may be formed of, for example, InP, and may be of the second conductivity type. The first cladding layer 29 and the second cladding layer 22 may be formed of, for example, InP, and may be of the second conductivity type. Details of the grating layer 24 and the optical confinement adjustment layer 30 are described later. The materials of the respective layers are merely examples. Here, in the following, a direction in which the layers are grown, in other words, a direction normal to the substrate 32 is represented by a third direction D3.

The semiconductor laser 1 may include a buried layer 44. The buried layer 44 may be arranged in contact with the mesa structure 10 on each of both sides of the mesa structure 10. The buried layer 44 may be formed of a semi-insulating semiconductor. For example, the buried layer 44 may be formed of semi-insulating InP (for example, Fe—InP). The buried layer 44 may be formed of a multilayer structure of an n-type semiconductor layer and a p-type semiconductor layer.

The semiconductor laser 1 may include a first facet 46 and a second facet 48 on a side opposite to the first facet 46. On each of the first facet 46 and the second facet 48, a low-reflection coating film (not shown) may be formed. The low-reflection coating film may have a reflectance of 1% or less. The mesa structure 10 may extend in a direction (first direction D1) in which the first facet 46 and the second facet 48 are connected to each other. The mesa structure 10 is not required to reach the first facet 46 and/or the second facet 48. For example, a window structure may be included between the mesa structure 10 and the first facet 46 and/or the second facet 48.

The semiconductor laser 1 may include a back surface electrode 40 on a side on which the mesa structure 10 of the substrate 32 is not formed. Further, the semiconductor laser 1 may include a front surface electrode 42 on an upper surface of the mesa structure 10 and a part of an upper surface of the buried layer 44. A contact layer of the second conductivity type may be arranged between the front surface electrode 42 and the second cladding layer 22. The front surface electrode 42 may be arranged across both of a first region 12 and a second region 14 which are to be described later, and injects the same current to the two regions. The back surface electrode 40 and the front surface electrode 42 may be used to inject a current supplied from an external power supply (not shown) to the semiconductor laser 1. The front surface electrode 42 may be arranged in a divided manner individually in an upper part of the first region 12 and an upper part of the second region 14. At this time, the same current may be injected to the first region 12 and the second region 14, or different currents may be injected thereto.

The semiconductor laser 1 may include an insulating film 38 on the upper surface of the buried layer 44 except for the vicinity of the upper surface of the mesa structure 10. The insulating film 38 is, for example, a silicon oxide or a silicon nitride.

The grating layer 24 may have a grating structure in which two regions having different refractive indices are alternately arranged in the first direction D1. In this case, the grating layer 24 may be regarded as a floating grating structure which is arranged between the spacer layer 18 and the first cladding layer 29. The grating layer 24 may include the phase shift portion 25. For example, the phase shift portion 25 may be a λ/4 phase shift portion. The grating layer 24 reflects light generated in the active layer 16, and the semiconductor laser 1 may be formed so as to oscillate at a 1.3 micrometer (μm) band. The wavelength band is not limited to the 1.3 μm band, and may be a 1.55 μm band or other wavelength bands. In this case, the grating layer 24 extends in the first direction D1 between the first facet 46 and the second facet 48. The thickness of the grating layer 24 in the third direction D3 may be the same throughout the entire region. Here, the phrase “the thickness may be the same” means that the thickness is the same within a range of manufacturing variation, and means that the thickness is not intentionally varied. As described later, an effective refractive index in the optical axis direction is not constant due to the difference in refractive index between a high refractive index region 51 and a low refractive index region 52 which may be included in the optical confinement adjustment layer 30. Accordingly, a grating period is not constant throughout the entire region, and the grating period may be finely adjusted in accordance with the effective refractive index so that a desired Bragg wavelength may be obtained.

The optical confinement adjustment layer 30 may be sandwiched between the first cladding layer 29 and the second cladding layer 22. The optical confinement adjustment layer 30 may include the high refractive index region 51 and the low refractive index region 52. The high refractive index region 51 and the low refractive index region 52 may be arranged adjacent to each other in the first direction D1. In the first direction D1, the high refractive index region 51 may be arranged on the first facet 46 side, and the low refractive index region 52 may be arranged on the second facet 48 side. The high refractive index region 51 may have a refractive index that is larger than a refractive index of the low refractive index region 52. The high refractive index region 51 may be formed of, for example, InGaAsP or InGaAlAs. In this case, the low refractive index region 52 is formed of InP. FIG. 2 and FIG. 4 show an interface between the low refractive index region 52 and each of the first cladding layer 29 and the second cladding layer 22 by a line, but, in some cases, the low refractive index region 52 may be formed of the same material as those of the two cladding layers, and thus the interface may be unclear in an actual case. Both of the optical confinement adjustment layer 30 in the high refractive index region 51 and the optical confinement adjustment layer 30 in the low refractive index region 52 may be flat films. When the optical confinement adjustment layer 30 in the low refractive index region 52, the first cladding layer 29, and the second cladding layer 22 are formed of the same material, an upper surface of the optical confinement adjustment layer 30 in the low refractive index region 52 may be regarded as being flush with an upper surface of the optical confinement adjustment layer 30 in the high refractive index region 51 (that is, having the same position in the third direction D3). The low refractive index region 52 may be formed of a material different from that of the first cladding layer 29 or the second cladding layer 22. The high refractive index region 51 and the low refractive index region 52 each may have a refractive index lower than that of the active layer 16. A composition wavelength may be set so that the optical confinement adjustment layer 30 is prevented from absorbing light in a Bragg wavelength. The high refractive index region 51 may have a refractive index that is higher than that of the second cladding layer 22. Further, the high refractive index region 51 may be thicker than the active layer 16 in the third direction D3. The optical confinement adjustment layer 30 may be of the second conductivity type.

Here, the semiconductor multilayer may be divided into the first region 12 including the high refractive index region 51 and the second region 14 including the low refractive index region 52. In the first example implementation, the phase shift portion 25 is included in the second region 14.

A coupling coefficient κ indicating an intensity of interaction between the grating structure of the semiconductor laser 1 and light may have a distribution in the optical axis direction (first direction D1). A coupling coefficient of the first region 12 is represented by κ1, and a coupling coefficient of the second region 14 is represented by κ2. In the first example implementation, κ1 may be larger than κ2. The coupling coefficient κ is determined based on the thickness of the grating layer 24 in the third direction D3, the refractive index of the grating layer 24, and the like. The grating layer 24 may have the same thickness in the first region 12 and the second region 14, and the first region 12 and the second region 14 may have the same semiconductor multilayer structure except for the structure of the optical confinement adjustment layer 30 and presence or absence of the phase shift portion 25. The phase shift portion 25 may be merely a small part of the grating layer 24, and the influence on the effective refractive index may be ignored in effect. Thus, the difference in effective refractive index between the first region 12 and the second region 14 may be mainly caused by the structure of the optical confinement adjustment layer 30, that is, the difference in refractive index between the high refractive index region 51 and the low refractive index region 52.

The high refractive index region 51 may have a refractive index that is higher than that of the low refractive index region 52. Accordingly, the distribution of the propagating light may be different between the first region 12 and the second region 14. In the first example implementation, the thickness of the high refractive index region 51 in the third direction D3 may be set so that the distribution of light propagating through the first region 12 becomes a distribution coming closer to the optical confinement adjustment layer 30 side as compared to the case of the second region 14. Accordingly, an optical confinement rate in the grating layer 24 may be larger in the first region 12 than in the second region 14. As a result, the coupling coefficient κ1 of the first region 12 may be larger than the coupling coefficient κ2 of the second region 14.

When the optical confinement adjustment layer 30 may be formed so as to include the high refractive index region 51 and the low refractive index region 52, a distribution may be provided in the coupling coefficient κ in the optical axis direction. Here, a length of the first region 12 in the first direction D1 may be represented by L1, and a length of the second region 14 in the first direction D1 may be represented by L2. For example, when a normalized coupling coefficient κ2L2 of the second region 14 is set to be smaller than a normalized coupling coefficient κ1L1 of the first region 12, the intensity of light output from the second facet 48 can be increased to be larger than the intensity of light output from the first facet 46. Through use of this feature, a high output laser may be achieved. Moreover, the present invention may be also excellent in single-wavelength characteristic because the low-reflection coating film may be formed on each of the first facet 46 and the second facet 48 and the λ/4 phase shift portion may be provided. In general, in a semiconductor laser used in optical communications, light output from only one of the facets may be used. Accordingly, it may be desired to increase the intensity of light output from one of the facets (in this case, the second facet 48). In order to achieve this state, the difference between κ1 and κ2 may be required to be increased. In order to increase the difference, the thickness of the optical confinement adjustment layer 30 in the high refractive index region 51 in the third direction D3 may be desired to be equal to or larger than the thickness of the active layer 16. In the following, the thickness of the optical confinement adjustment layer 30 in the high refractive index region 51 in the third direction D3 may be referred to as “the thickness of the high refractive index region 51.” The thickness of the optical confinement adjustment layer 30 in the low refractive index region 52 in the third direction D3 may be referred to as “the thickness of the low refractive index region 52.”

Further, in the first example implementation, the thickness of the grating layer 24 in the third direction D3 may be constant, and the grating layer 24 may have the same thickness in the first region 12 and the second region 14. Accordingly, as compared to a means for adjusting the coupling coefficient by changing the thickness of the grating layer, the first example implementation may be superior in easiness of manufacture. Similarly, the composition of the semiconductor layer does not vary within the grating layer in the optical axis direction, and hence the semiconductor laser may be manufactured by a simpler manufacturing method. Moreover, when the distribution of the coupling coefficient is provided by adjusting the thickness or the composition of the grating layer, from the viewpoint of manufacturing performance, it may be difficult to achieve a large coupling coefficient difference. For example, the difference in coupling coefficient may be increased by greatly changing the thickness of the grating layer in the first region 12 and the thickness of the grating layer in the second region 14, but formation of a grating layer having a step itself is difficult, and there is a risk that this step may adversely affect the next manufacturing process. Meanwhile, in the first example implementation, the coupling coefficient is adjusted by a configuration of the optical confinement adjustment layer 30, which is a layer different from the grating layer 24, and hence a desired coupling coefficient can be obtained separately from the design of the grating layer.

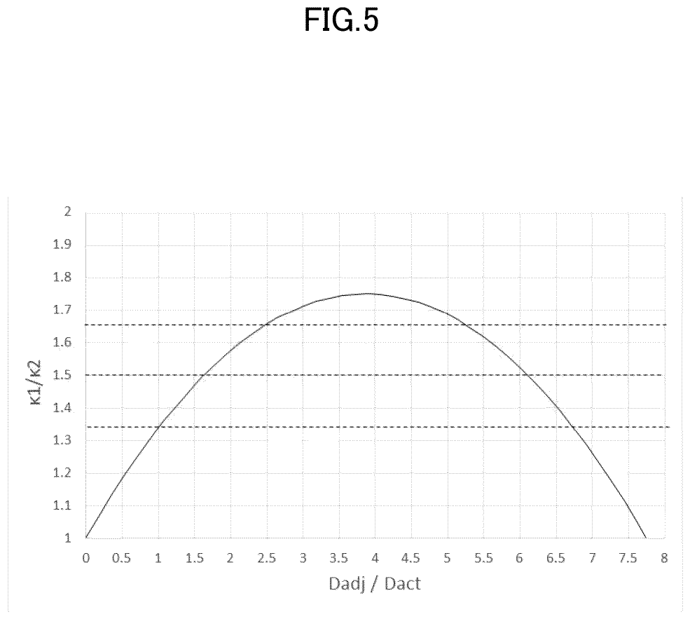

FIG. 5 shows calculation results indicating an example relationship between the thickness of the high refractive index region 51 and the coupling coefficient. The horizontal axis represents a ratio (Dadj/Dact) of a thickness Dadj of the high refractive index region 51 to a thickness Dact of the active layer 16. The vertical axis represents a ratio (κ1/κ2) of the coupling coefficient κ1 of the first region 12 to the coupling coefficient κ2 of the second region 14. The position of 0 of the horizontal axis indicates a case in which no high refractive index region 51 is arranged, in other words, a case in which the high refractive index region 51 and the low refractive index region 52 have the same refractive index. In this case, κ1 and κ2 have the same value, and hence the vertical axis becomes 1. As κ1/κ2 becomes larger, the output intensity of light output from the second facet 48 becomes larger, and the output intensity of light output from the first facet 46 becomes smaller. In general, when the thickness Dact of the active layer 16 is large, the optical confinement rate of the active layer 16 is increased. In accordance therewith, the optical confinement rate of the grating layer 24 is decreased. The optical confinement rate of the grating layer 24 cannot be increased unless the thickness of the high refractive index region 51 of the optical confinement adjustment layer 30 is sufficiently increased. That is, it is required to appropriately set Dadj in accordance with Dact. This setting is indicated by the horizontal axis of FIG. 5.

In some implementations, when κ1/κ2 is 1.33 or more, κ1/κ2 is sufficient as the light output intensity for a light source of optical communications. In order to achieve this state, Dadj/Dact may be required to be set to 1 or more and 6.7 or less. That is, it may be desired that the high refractive index region 51 at least have a thickness that is equal to or larger than the active layer thickness Dact. Further, in order to meet the requirements of the high-output semiconductor laser in recent years, κ1/κ2 may be desired to be 1.5 or more. Dadj/Dact may be 1.6 or more and 6.2 or less. Moreover, along with an increase in optical communication amount, in order to respond to the rise of environment temperature (rise of drive temperature) due to high-density mounting of optical components and to low power consumption drive, a higher-output semiconductor laser may be desired. In order to meet those requirements, κ1/κ2 may be desired to be 1.65 or more, and Dadj/Dact may be desired to be 2.5 or more and 5.25 or less. FIG. 5 shows results calculated for the case in which the low refractive index region 52 is InP.

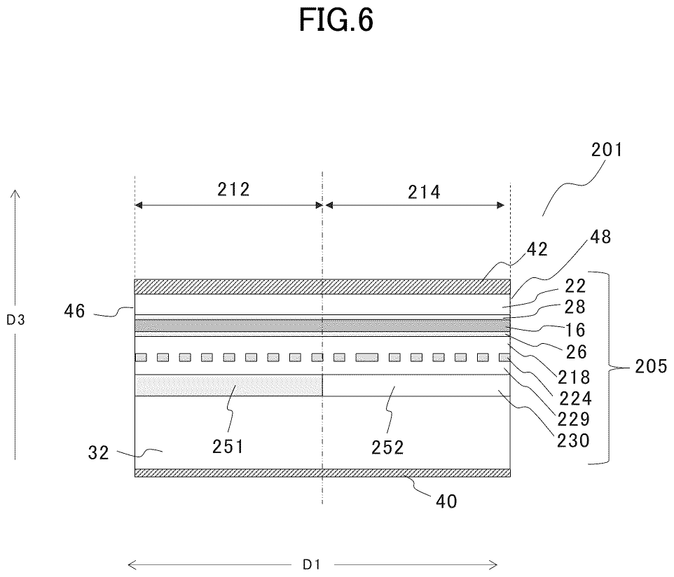

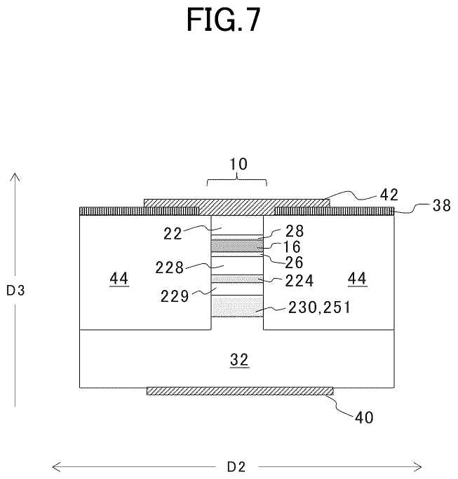

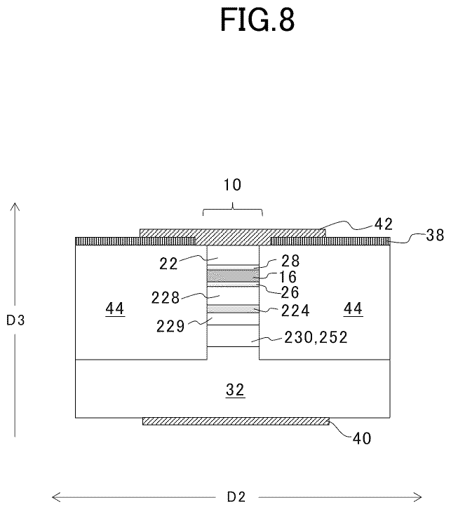

FIG. 6 is a schematic sectional view taken along a direction along an optical axis of a semiconductor laser 201 according to a second example implementation of the present invention, and corresponds to the schematic sectional view taken along the line II-II of FIG. 1. FIG. 7 corresponds to the schematic sectional view taken along the line III-III of FIG. 1. FIG. 8 corresponds to the schematic sectional view taken along the line IV-IV of FIG. 1.

In a semiconductor multilayer 205 of the semiconductor laser 201, from the substrate 32 side, an optical confinement adjustment layer 230, a first cladding layer 229, a grating layer 224, a spacer layer 218, the first optical confinement layer 26, the active layer 16, the second optical confinement layer 28, and the second cladding layer 22 are grown in the stated order. Similarly to the first example implementation, the optical confinement adjustment layer 230 may include a high refractive index region 251 and a low refractive index region 252. Similarly to the first example implementation, the high refractive index region 251 may have a refractive index that is higher than that of the low refractive index region 252. The optical confinement adjustment layer 230 may be of the first conductivity type. Although the position arranged in the third direction D3 is different, other than that, the grating layer 224 and the grating structure have the same structures as those in the first example implementation.

Also in the second example implementation, a region in which the high refractive index region 251 is arranged may be regarded as a first region 212, and a region in which the low refractive index region 252 is arranged is may be regarded as a second region 214. Similarly to the first example implementation, in the first region 212, the distribution of propagating light comes closer to the high refractive index region 251 side due to the high refractive index region 251, and hence the coupling coefficient κ1 of the first region 212 becomes larger than the coupling coefficient κ2 of the second region 214.

As described above, even in the structure in which the grating layer 224 is arranged between the active layer 16 and the substrate 32, when the optical confinement adjustment layer 230 is arranged between the grating layer 224 and the substrate 32, the distribution of the coupling coefficient can be formed in the optical axis direction.

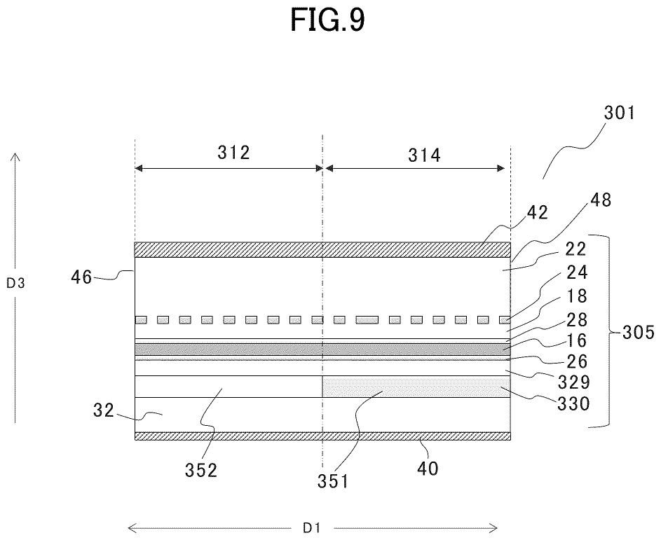

FIG. 9 is a schematic sectional view taken along a direction along an optical axis of a semiconductor laser 301 according to a third example implementation of the present invention, and corresponds to the schematic sectional view taken along the line II-II of FIG. 1.

In a semiconductor multilayer 305 of the semiconductor laser 301, from the substrate 32 side, an optical confinement adjustment layer 330, a first cladding layer 329, the first optical confinement layer 26, the active layer 16, the second optical confinement layer 28, the spacer layer 18, the grating layer 24, and the second cladding layer 22 are grown in the stated order. Similarly to the first example implementation, the optical confinement adjustment layer 330 may include a high refractive index region 351 and a low refractive index region 352. Similarly to the first example implementation, the high refractive index region 351 may have a refractive index that may be higher than that of the low refractive index region 352. The optical confinement adjustment layer 330 may be of the first conductivity type.

In the third example implementation, a region in which the low refractive index region 352 is arranged may be regarded as a first region 312, and a region in which the high refractive index region 351 is arranged is may be regarded as a second region 314. In the second region 314, the high refractive index region 351 is arranged, and hence the distribution of the propagating light may be pulled to the high refractive index region 351 side. Accordingly, the optical confinement rate of the grating layer 24 in the second region 314 may be lower than that in the first region 312, and κ2 may be smaller than κ1. In the first and second example implementations, the high refractive index regions 51 and 251 are arranged in order to increase the optical confinement rate of the grating layer, but, in the third example implementation, the high refractive index region 351 is arranged in order to decrease the optical confinement rate of the grating layer. In any case, the coupling coefficient κ of the first region 312 can be increased to be larger than that of the second region 314.

As described above, the first region is not defined by the region in which the high refractive index region of the optical confinement adjustment layer is arranged, but is defined by the region whose coupling coefficient is increased to be larger by the optical confinement adjustment layer formed of the two refractive index regions.

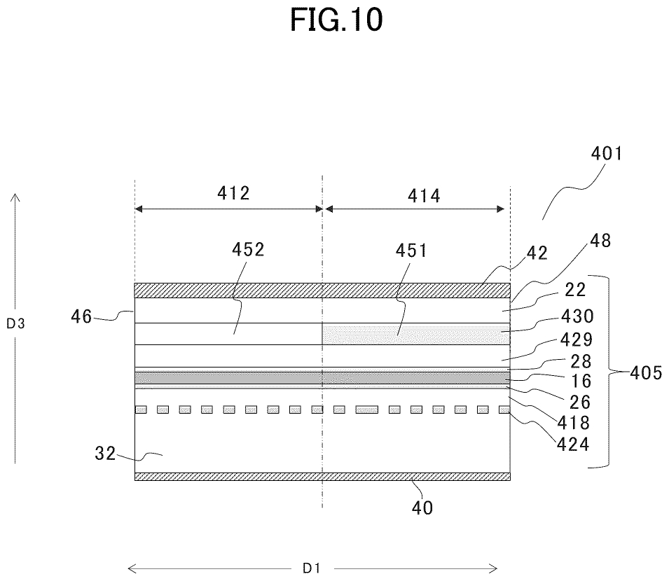

FIG. 10 is a schematic sectional view taken along a direction along an optical axis of a semiconductor laser 401 according to a fourth example implementation of the present invention, and corresponds to the schematic sectional view taken along the line II-II of FIG. 1.

In a semiconductor multilayer 405 of the semiconductor laser 401, from the substrate 32 side, a grating layer 424, a spacer layer 418, the first optical confinement layer 26, the active layer 16, the second optical confinement layer 28, a first cladding layer 429, an optical confinement adjustment layer 430, and the second cladding layer 22 are grown in the stated order. Similarly to the first example implementation, the optical confinement adjustment layer 430 may include a high refractive index region 451 and a low refractive index region 452. Similarly to the first example implementation, the high refractive index region 451 may have a refractive index that is higher than that of the low refractive index region 452. The optical confinement adjustment layer 430 may be of the second conductivity type.

In the fourth example implementation, a region in which the low refractive index region 452 is arranged is may be regarded as a first region 412, and a region in which the high refractive index region 451 is arranged is may be regarded as a second region 414. Similarly to the third example implementation, in the second region 414, the optical confinement rate in the grating layer becomes smaller than that in the first region 412 due to the high refractive index region 451. Accordingly, similarly to other embodiments, the distribution of the coupling coefficient can be formed in the first direction D1.

As described above, the semiconductor laser in the present invention may include an active layer and a grating layer (grating structure), and may have a feature in that an optical confinement adjustment layer including a high refractive index region and a low refractive index region may be arranged above or below those two structures in a stacking direction (third direction D3). The optical confinement rate of the grating layer may be adjusted by the high refractive index region, and thus the coupling coefficient may be varied from that of the region in which the low refractive index region may be arranged. The order to grow the active layer and the grating layer is not limited. Each of those two layers and the spacer layer arranged between the two layers may have the same structure in the optical axis direction. The coupling coefficient of the semiconductor laser may be mainly determined by the active layer, the grating layer, and the spacer layer. This coupling coefficient serving as a base may be adjusted by arranging the optical confinement adjustment layer so that the distribution of the coupling coefficient may be formed in the optical axis direction. The distribution of the coupling coefficient allows effects such as an increase in light output intensity from one facet to be obtained.

When the region having a large coupling coefficient is regarded as the first region and the region having a coupling coefficient that is smaller than that of the first region is regarded as the second region, in a case in which the high refractive index region is arranged in the first region, the low refractive index region is arranged in the second region. This arrangement corresponds to a case in which the coupling coefficient is increased by increasing the optical confinement rate of the grating layer by the high refractive index region. Conversely, in a case in which the low refractive index region is arranged in the first region and the high refractive index region is arranged in the second region, the coupling coefficient of the second region is decreased by decreasing the optical confinement rate of the grating layer by the high refractive index region in the second region. As described above, the high refractive index region is arranged in any one of the first region or the second region and the low refractive index region is arranged in another one of the first region or the second region so that the first coupling coefficient of the first region becomes larger than the second coupling coefficient of the second region.

In the first example implementation and the fourth example implementation, in the stacking direction that is the third direction D3, the optical confinement adjustment layer is arranged above the grating layer and the active layer. Multilayers of the semiconductor multilayer are grown in order from the substrate 32 toward the upper side of FIG. 2 or FIG. 10. The optical confinement adjustment layer is formed of the high refractive index region and the low refractive index region which have different refractive indices. When those two regions are formed to have the same thickness, there is a risk that a step is generated between those regions. In particular, as described above, in order to generate a large difference in coupling coefficient between the first region and the second region, it may be preferred that the optical confinement adjustment layer be thicker. When the layer thickness is large, there is a risk that this step becomes large. When the grating layer and the active layer are arranged above the region in which the step is generated, there is a risk that a step is generated also in those layers. The step of the grating layer or the active layer becomes a cause of degradation of an optical characteristic. However, in the first example implementation and the fourth example implementation, the optical confinement adjustment layer is formed above the active layer and the grating layer, and hence the step of the optical confinement adjustment layer does not affect the active layer or the grating layer. Accordingly, a semiconductor laser that is more excellent in manufacturing performance can be achieved.

In the second example implementation and the third example implementation, the grating layer and the active layer are arranged above the optical confinement adjustment layer, and hence there is a risk that the step of the optical confinement adjustment layer affects the grating layer or the active layer. However, the first cladding layer may be arranged above the optical confinement adjustment layer. Thus, the step of the optical confinement adjustment layer becomes smaller, and the influence on the grating layer and the active layer can be reduced.

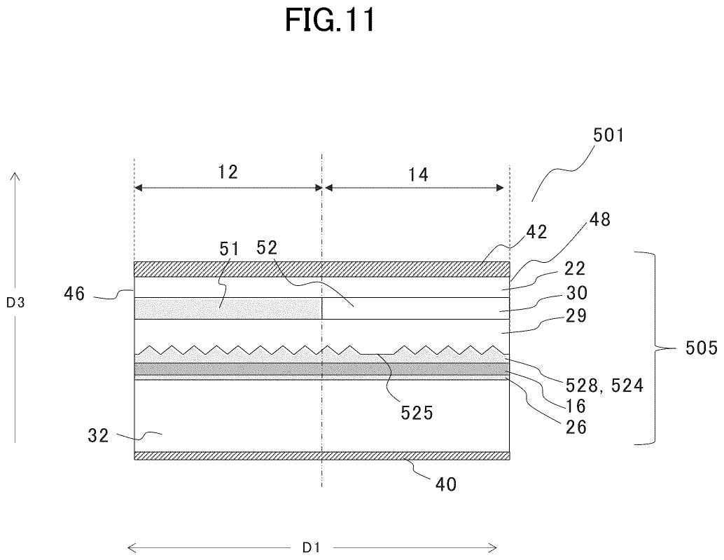

FIG. 11 is a schematic sectional view taken along a direction along an optical axis of a semiconductor laser 501 according to a fifth example implementation of the present invention, and corresponds to the schematic sectional view taken along the line II-II of FIG. 1.

The semiconductor laser 501 and the semiconductor laser 1 of the first example implementation may have a difference in grating structure. In a semiconductor multilayer in the fifth example implementation, from the substrate 32 side, the first optical confinement layer 26, the active layer 16, a second optical confinement layer 528, the first cladding layer 29, the optical confinement adjustment layer 30, and the second cladding layer 22 are grown in the stated order. The grating structure may be formed on the front surface side of the second optical confinement layer 528. That is, the second optical confinement layer 528 may have a function as the grating layer 524 in addition to the function as the optical confinement layer. The grating structure may be formed of a protruding region of the second optical confinement layer 528 (grating layer 524) whose surface may be protruded and the first cladding layer 29 arranged between two protruding regions. The refractive index of the second optical confinement layer 528 may be higher than the refractive index of the first cladding layer 29. Further, the grating structure may include a phase shift portion 525. As shown in the fifth example implementation, no spacer layer is required when the grating structure is formed in the second optical confinement layer 528.

Also in the fifth example implementation, with the high refractive index region 51 being provided, the coupling coefficient κ1 of the first region 12 becomes larger than the coupling coefficient κ2 of the second region 14. In the first example implementation, instead of forming the grating structure of a floating type, unevenness may be provided on the surface of the grating layer as shown in the fifth example implementation.

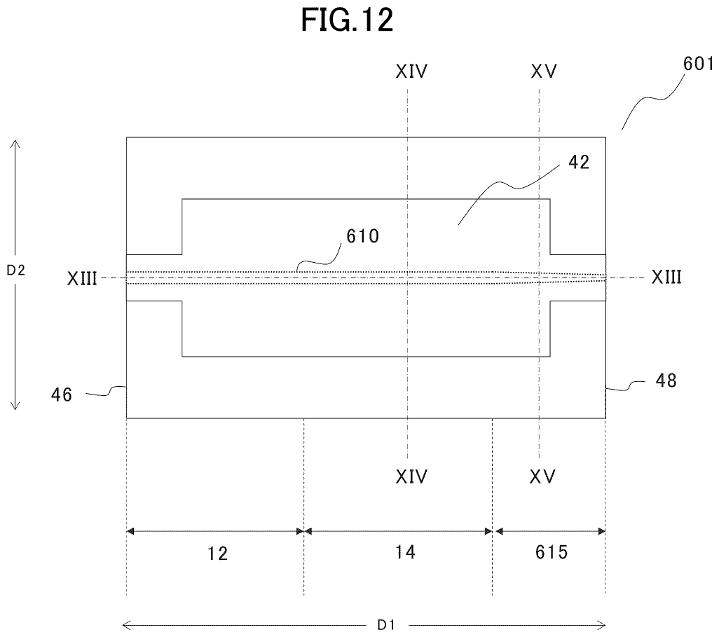

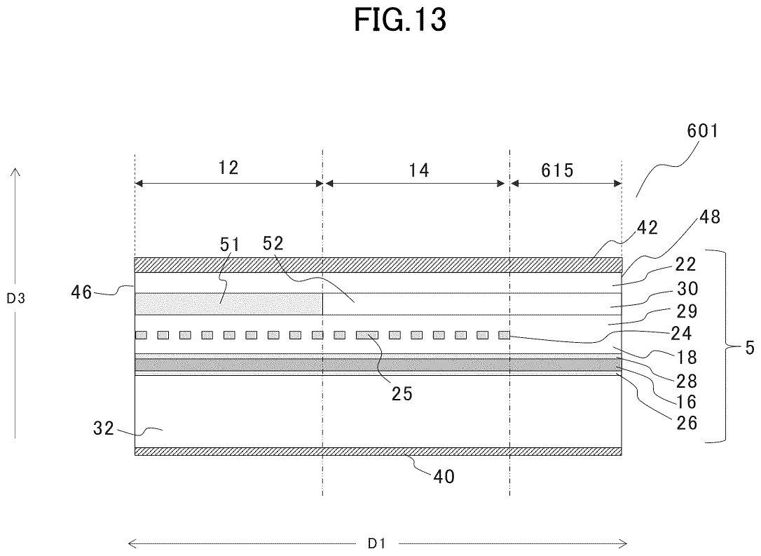

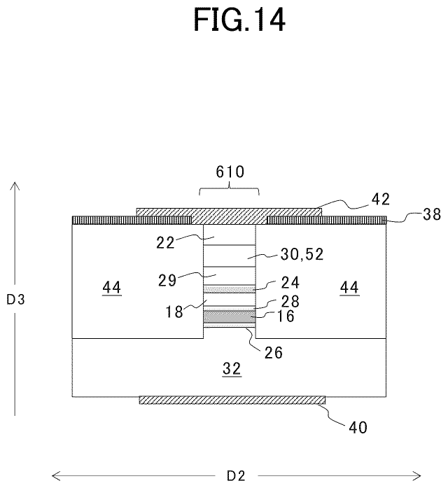

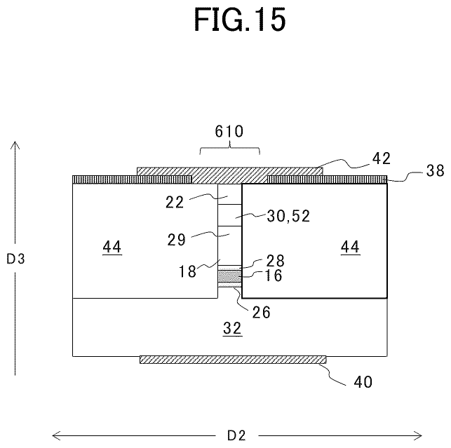

FIG. 12 is a top view for illustrating a semiconductor laser 601 according to a sixth example implementation of the present invention. FIG. 13 is a schematic sectional view taken along the line XIII-XIII of the semiconductor laser 601 illustrated in FIG. 12. FIG. 14 is a schematic sectional view taken along the line XIV-XIV of the semiconductor laser 601 illustrated in FIG. 12. FIG. 15 is a schematic sectional view taken along the line XV-XV of the semiconductor laser 601 illustrated in FIG. 12.

The semiconductor laser 601 according to the sixth example implementation and the semiconductor laser 1 according to the first example implementation have a difference in that, in addition to the first region 12 and the second region 14, a third region 615 is arranged adjacent in the stated order along the first direction D1. The semiconductor multilayer 5 of the third region 615 may be the same as that of the second region 14 in the first example implementation except that the semiconductor multilayer 5 does not include the grating layer 24, and the first cladding layer 29 and the spacer layer 18 are in contact with each other. The semiconductor multilayers 5 of the first region 12 and the second region 14 may have the same structures as those in the first example implementation. The front surface electrode 42 and the back surface electrode 40 may be arranged across the first region 12, the second region 14, and the third region 615, and inject the same current to the three regions.

A width (mesa width) of a mesa structure 610 in the third region 615 may be gradually reduced toward the second facet 48. As the mesa width becomes thinner, the optical confinement rate of the mesa structure 610 is decreased and a near field pattern (NFP) in the third direction D3 is enlarged. With the shape of the NFP being adjusted, the third region 615 functions as a spot size conversion part that can adjust a divergence angle of a far field pattern (FFP) in the vertical direction. As a result of arranging the optical confinement adjustment layer 30 in order to adjust the coupling coefficient, in some cases, a desired FFP cannot be obtained. When the third region 615 is arranged at this place, the FFP can be adjusted. Further, the third region 615 may include the active layer 16 and may have a structure to which a current is injected, and hence an effect of amplifying light is also provided.

The mesa width of the third region 615 may be gradually increased toward the second facet 48. The mesa width is only required to be adjusted in accordance with the target FFP specifications. Moreover, the mesa width may be constant. When the mesa width is constant, the third region 615 purely functions as a semiconductor optical amplifier for amplifying light. The example implementation described here is merely an example, and, as a matter of course, the third region 615 may be added between the first region 12 and the first facet 46.

The present invention is not limited to the above-mentioned embodiments, and various modifications may be made thereto. For example, the number of regions having different refractive indices included in the optical confinement adjustment layer is not limited to two, and may be three or more.

The present invention is a semiconductor laser in which a distribution is provided in a coupling coefficient in an optical axis direction. The example implementations of the present invention achieve the semiconductor laser by including an active layer, a grating layer, and an optical confinement adjustment layer including a high refractive index region and a low refractive index region, and by adjusting an optical confinement rate of the grating layer by the high refractive index region. The optical confinement rate of the grating layer may be increased by the high refractive index region so that a region having a large coupling coefficient may be formed, or the optical confinement rate of the grating layer may be decreased by the high refractive index region so that a region having a small coupling coefficient may be formed. In the grating layer, the first region having a large coupling coefficient and the second region having a small coupling coefficient have a common structure, and the coupling coefficient is adjusted by the optical confinement adjustment layer. The optical confinement adjustment layer may be arranged above the grating layer, or may be arranged between the substrate and the grating layer. It may be preferred that the thickness of the high refractive index region be equal to or larger than the thickness of the active layer. In order to obtain a high output characteristic, a ratio of the thickness of the high refractive index region to the thickness of the active layer is preferably 1.6 or more and 6.2 or less, more preferably 2.5 or more and 5.25 or less. The semiconductor laser may further include a window structure, a spot size conversion part, and an optical amplifier.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more. ” Further, as used herein, the article “the” is intended to include one or more items referenced in connection with the article “the” and may be used interchangeably with “the one or more. ” Furthermore, as used herein, the term “set” is intended to include one or more items (e.g., related items, unrelated items, or a combination of related and unrelated items), and may be used interchangeably with “one or more. ” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a substrate; and
a semiconductor multilayer arranged above the substrate,
wherein the semiconductor multilayer includes an active layer, a grating layer, and an optical confinement adjustment layer which is flat,
wherein the semiconductor multilayer forms a first region and a second region in a first direction in which the grating layer extends,
wherein the optical confinement adjustment layer includes a high refractive index region, and a low refractive index region having a refractive index lower than a refractive index of the high refractive index region, and
wherein the high refractive index region is arranged in any one of the first region or the second region and the low refractive index region is arranged in another one of the first region or the second region so that a first coupling coefficient of the first region becomes larger than a second coupling coefficient of the second region.

2. The semiconductor laser according to claim 1, wherein the optical confinement adjustment layer is arranged so as to avoid passing between the active layer and the grating layer.

3. The semiconductor laser according to claim 1,
wherein, in the semiconductor multilayer, above the substrate, the active layer, the grating layer, and the optical confinement adjustment layer are grown in the stated order,
wherein the first region includes the high refractive index region, and
wherein the second region includes the low refractive index region.

4. The semiconductor laser according to claim 1,
wherein, in the semiconductor multilayer, above the substrate, the optical confinement adjustment layer, the grating layer, and the active layer are grown in the stated order,
wherein the first region includes the high refractive index region, and
wherein the second region includes the low refractive index region.

5. The semiconductor laser according to claim 1,
wherein, in the semiconductor multilayer, above the substrate, the optical confinement adjustment layer, the active layer, and the grating layer are grown in the stated order,
wherein the first region includes the low refractive index region, and
wherein the second region includes the high refractive index region.

6. The semiconductor laser according to claim 1,
wherein, in the semiconductor multilayer, above the substrate, the grating layer, the active layer, and the optical confinement adjustment layer are grown in the stated order,
wherein the first region includes the low refractive index region, and
wherein the second region includes the high refractive index region.

7. The semiconductor laser according to claim 1, wherein the grating layer includes a phase shift portion.

8. The semiconductor laser according to claim 7, wherein the phase shift portion is included in the second region.

9. The semiconductor laser according to claim 1, further comprising an electrode arranged above the semiconductor multilayer,
wherein the semiconductor multilayer includes a cladding layer between the active layer and the electrode.

10. The semiconductor laser according to claim 9, wherein the refractive index of the high refractive index region is higher than a refractive index of the cladding layer.

11. The semiconductor laser according to claim 9, wherein the refractive index of the low refractive index region is equal to a refractive index of the cladding layer.

12. The semiconductor laser according to claim 9, wherein the refractive index of the low refractive index region is different from a refractive index of the cladding layer.

13. The semiconductor laser according to claim 1, wherein the optical confinement adjustment layer is arranged so as to be separated away from the grating layer.

14. The semiconductor laser according to claim 1, wherein the first region has a normalized coupling coefficient that is larger than a normalized coupling coefficient of the second region.

15. The semiconductor laser according to claim 1, wherein, in a stacking direction of the semiconductor multilayer, the high refractive index region has a thickness that is equal to or larger than a thickness of the active layer.

16. The semiconductor laser according to claim 15, wherein, in the stacking direction of the semiconductor multilayer, the thickness of the high refractive index region is equal to or larger than 1 times the thickness of the active layer and equal to or smaller than 6.7 times the thickness of the active layer.

17. The semiconductor laser according to claim 15, wherein, in the stacking direction of the semiconductor multilayer, the thickness of the high refractive index region is equal to or larger than 2.5 times the thickness of the active layer and equal to or smaller than 5.25 times the thickness of the active layer.

18. The semiconductor laser according to claim 1, further comprising a third region in contact with one of the first region or the second region in the first direction,
wherein the third region is prevented from including the grating layer.

19. The semiconductor laser according to claim 18,
wherein the semiconductor multilayer includes a mesa structure, and
wherein the semiconductor multilayer has a width in a direction perpendicular in plan view to a direction in which the mesa structure extends, the width being gradually reduced or gradually increased in the third region with respect to widths of the first region and the second region, toward a facet in the direction in which the mesa structure extends.

20. The semiconductor laser according to claim 18,
wherein the third region includes the active layer, and
wherein the semiconductor laser further comprises an electrode arranged across the first region, the second region, and the third region.
